(19) United States
(12) Patent Application Publication
(10) Pub. No.: US 2025/0234580 A1
(43) Pub. Date: Jul. 17, 2025

(54) INTEGRATED CIRCUIT DEVICE

(71) Applicant: SAMSUNG ELECTRONICS CO., LTD., Suwon-si (KR)

(72) Inventors: Sumin Yu, Suwon-si (KR); Jungtaek Kim, Suwon-si (KR); Moonseung Yang, Suwon-si (KR); Yonguk Jeon, Suwon-si (KR); Edward Namkyu Cho, Suwon-si (KR); Seokhoon Kim, Suwon-si (KR); Pankwi Park, Suwon-si (KR)

(21) Appl. No.: 19/011,371

(22) Filed: Jan. 6, 2025

(30) Foreign Application Priority Data
Jan. 12, 2024 (KR) 10-2024-0005566

(51) Int. Cl. H10D 30/00; H10D 30/01

(52) U.S. Cl. CPC H10D 30/502; H10D 30/0191

(57) ABSTRACT

An integrated circuit device includes a substrate, a fin-type active area on the substrate, a nanosheet stacked structure including a plurality of nanosheets, a gate electrode surrounding the nanosheet stacked structure on the fin-type active area, and a source/drain region connected to one end of the plurality of nanosheets on the fin-type active area, wherein the source/drain region includes a first source/drain layer in contact with the upper surface of the fin-type active area and side surfaces of the plurality of nanosheets, a second source/drain layer covering the first source/drain layer, a third source/drain layer covering part of the second source/drain layer, and a fourth source/drain layer covering the second source/drain layer and the third source/drain layer.

### CROSS-REFERENCE TO RELATED APPLICATION

This application is based on and claims priority under 35 U.S.C. § 119 to Korean Patent Application No. 10-2024-0005566, filed in the Korean Intellectual Property Office on Jan. 12, 2024, the disclosure of which is incorporated by reference herein in its entirety.

### BACKGROUND

As the degree of integration of integrated circuit devices increases, the sizes of the devices have been reduced to an extreme and scaling of the devices has reached its limit. Accordingly, in order to improve the performance of a device, there is a need for finding a new method through changing the structure of the device, and integrated circuit devices including transistors having new structures such as MOSFETs have been proposed.

### SUMMARY

In general, in some aspects, the present disclosure is directed toward an integrated circuit device having a transistor including a multi-gate metal-oxide-semiconductor field-effect transistor (MOSFET) that ensures operational reliability.

According to some implementations, the present disclosure is directed to an integrated circuit device that includes a substrate, a fin-type active area extending in a first horizontal direction on the substrate, a nanosheet stacked structure including a plurality of nanosheets that are spaced apart from each other in a vertical direction and extend in parallel with an upper surface of the fin-type active area at positions spaced apart from the upper surface of the fin-type active area, a gate electrode surrounding the nanosheet stacked structure on the fin-type active area and extending in a second horizontal direction that crosses the first horizontal direction, and a source/drain region connected to one end of the plurality of nanosheets on the fin-type active area, wherein the source/drain region includes a first source/drain layer in contact with the upper surface of the fin-type active area and side surfaces of the plurality of nanosheets, a second source/drain layer covering the first source/drain layer, a third source/drain layer covering part of the second source/drain layer and having an uppermost end that is lower than an uppermost end of each of the first source/drain layer and the second source/drain layer, and a fourth source/drain layer covering the second source/drain layer and the third source/drain layer.

According to some implementations, the present disclosure is directed to an integrated circuit device that includes a substrate having a first area and a second area, a fin-type active area extending in a first horizontal direction in each of the first area and the second area, a nanosheet stacked structure including a plurality of nanosheets in each of the first area and the second area, the plurality of nanosheets being spaced apart in a vertical direction and extending in parallel with an upper surface of the fin-type active area at positions spaced apart from the upper surface of the fin-type active area, a gate electrode, which, in each of the first area and the second area, surrounds the nanosheet stacked structure on the fin-type active area and extends in a second horizontal direction crossing the first horizontal direction, and a first source/drain region which is, in the first area, connected to one end of the plurality of nanosheets on the fin-type active area, wherein the first source/drain region includes a first source/drain layer in contact with the upper surface of the fin-type active area and side surfaces of the plurality of nanosheets, having a first thickness on the side surfaces of the plurality of nanosheets, and having a second thickness on the upper surface of the fin-type active area, a second source/drain layer covering the first source/drain layer and having a third thickness that is less than each of the first thickness and the second thickness, a third source/drain layer covering part of the second source/drain layer and having an uppermost end that is lower than an uppermost end of each of the first source/drain layer and the second source/drain layer, and a fourth source/drain layer covering the second source/drain layer and the third source/drain layer, and the second source/drain layer extends between the first source/drain layer and the third source/drain layer and between the first source/drain layer and the fourth source/drain layer.

According to some implementations, the present disclosure is directed to an integrated circuit device that includes a substrate having a first area and a second area, a fin-type active area extending in a first horizontal direction in each of the first area and the second area, a nanosheet stacked structure including a plurality of nanosheets in each of the first area and the second area, the plurality of nanosheets being spaced apart in a vertical direction and extending in parallel with an upper surface of the fin-type active area at positions spaced apart from the upper surface of the fin-type active area, a gate electrode, which, in each of the first area and the second area, surrounds the nanosheet stacked structure on the fin-type active area and extends in a second horizontal direction crossing the first horizontal direction, a first source/drain region which is, in the first area, connected to one end of the plurality of nanosheets on the fin-type active area, and a second source/drain region which is, in the second area, connected to one end of the plurality of nanosheets on the fin-type active area, wherein the first source/drain region includes: a first source/drain layer in contact with the upper surface of the fin-type active area and side surfaces of the plurality of nanosheets, having a first thickness on the side surfaces of the plurality of nanosheets, and having a second thickness on the upper surface of the fin-type active area; a second source/drain layer covering the first source/drain layer and having a third thickness that is less than each of the first thickness and the second thickness; a third source/drain layer covering part of the second source/drain layer, having an uppermost end that is lower than an uppermost end of each of the first source/drain layer and the second source/drain layer, and having a concave upper surface; and a fourth source/drain layer covering the second source/drain layer and the third source/drain layer, the second source/drain region includes a fifth source/drain layer in contact with the upper surface of the fin-type active area and the side surfaces of the plurality of nanosheets, a sixth source/drain layer covering the fifth source/drain layer and having a convex upper surface, and a seventh source/drain layer covering the sixth source/drain layer and having a convex upper surface, and each of an uppermost end of the fourth source/drain layer and an uppermost end of the seventh source/drain layer is at a higher vertical level than an uppermost end of the nanosheet stacked structure.

### BRIEF DESCRIPTION OF THE DRAWINGS

Example implementations will be more clearly understood from the following detailed description, taken in conjunction with the accompanying drawings.

FIGS. 1 to 4, 5A, 5B, and 6 to 13 are cross-sectional views showing an example of a method of manufacturing an integrated circuit device according to some implementations.

FIGS. 14A, 14B, and 15 are cross-sectional views of an example of an integrated circuit device according to some implementations.

FIG. 16 is a cross-sectional view of an example of an integrated circuit device according to some implementations.

FIGS. 17 and 18 are cross-sectional views of examples of an integrated circuit device according to some implementations.

### DETAILED DESCRIPTION

Hereinafter, example implementations will be explained in detail with reference to the accompanying drawings.

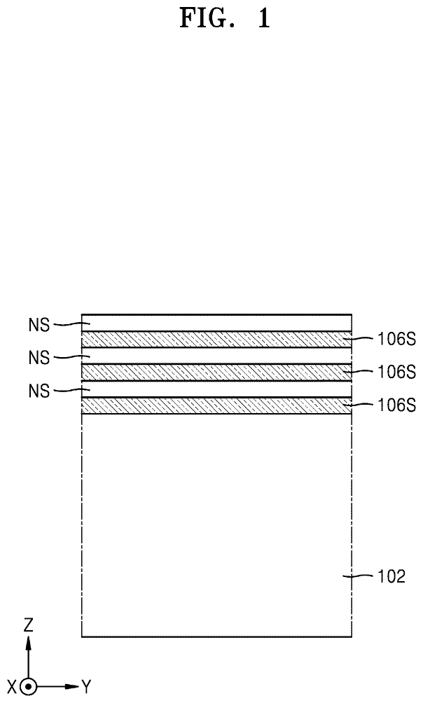

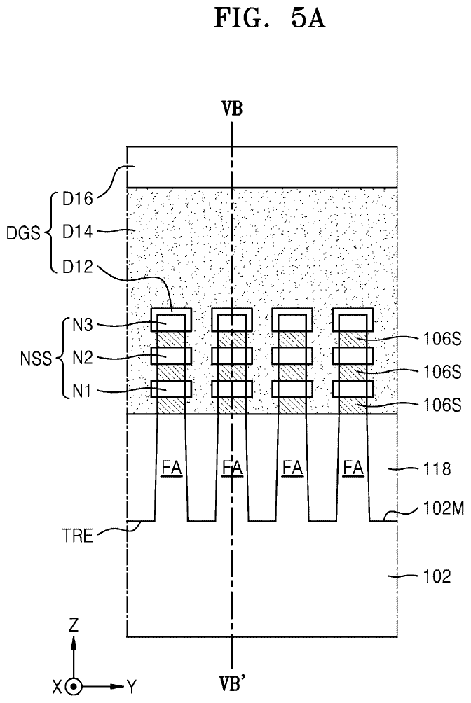

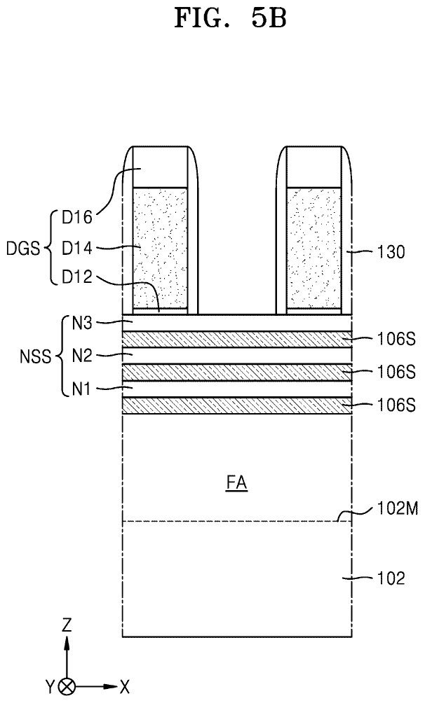

FIGS. 1 to 4, 5A, 5B, and 6 to 13 are cross-sectional views showing an example of a method of manufacturing an integrated circuit device according to some implementations. For example, FIGS. 1 to 4 and 5A are Y-Z vertical cross-sectional views, FIGS. 5B and 6 to 13 are X-Z cross-sectional views, and FIG. 5B is a cross-sectional view taken along line VB-VB′ of FIG. 5A.

In FIG. 1, a plurality of sacrificial semiconductor layers 106S and a plurality of nanosheet semiconductor layers NS may be alternately stacked one layer at a time on a substrate 102. The plurality of sacrificial semiconductor layers 106S and the plurality of nanosheet semiconductor layers NS may include different semiconductor layers. The plurality of sacrificial semiconductor layers 106S may include a material having etch selectivity with the plurality of nanosheet semiconductor layers NS. In some implementations, the plurality of nanosheet semiconductor layers NS may include a material that has the same or similar etch characteristics as a material of the substrate 102. In some implementations, the plurality of sacrificial semiconductor layers 106S may include silicon-germanium (SiGe) and the plurality of nanosheet semiconductor layers NS may include silicon (Si). However, the present disclosure is not limited thereto.

The plurality of sacrificial semiconductor layers 106S may all be formed with the same thickness, but the present disclosure is not limited thereto. In some implementations, a thickness of a sacrificial semiconductor layer 106S closest to the substrate 102 from among the plurality of sacrificial semiconductor layers 106S may be greater than thicknesses of the remaining sacrificial semiconductor layers 106S.

The substrate 102 may include a semiconductor material, such as Si or germanium (Ge), or a compound semiconductor material, such as SiGe, silicon carbide (SiC), gallium arsenide (GaAs), indium arsenide (InAs), or indium phosphide (InP). In some implementations, the substrate 102 may include at least one of a group III-V material and a group IV material. The group III-V material may be a binary, ternary, or quaternary compound semiconductor material containing at least one group III element and at least one group V element. The substrate 102 may include a conductive area, for example, a well doped with impurities or a structure doped with impurities. In some implementations, when an n-type metal-oxide-semiconductor field-effect transistor (NMOS) is formed on part of the substrate 102, the part of the substrate 102 may include one of the group III-V materials described above. In some implementations, when a p-type metal-oxide-semiconductor field-effect transistor (PMOS) is formed on part of the substrate 102, the part of the substrate 102 may include Ge. In another example, the substrate 102 may have a silicon on insulator (SOI). The substrate 102 may include a conductive area, for example, a well doped with impurities or a structure doped with impurities.

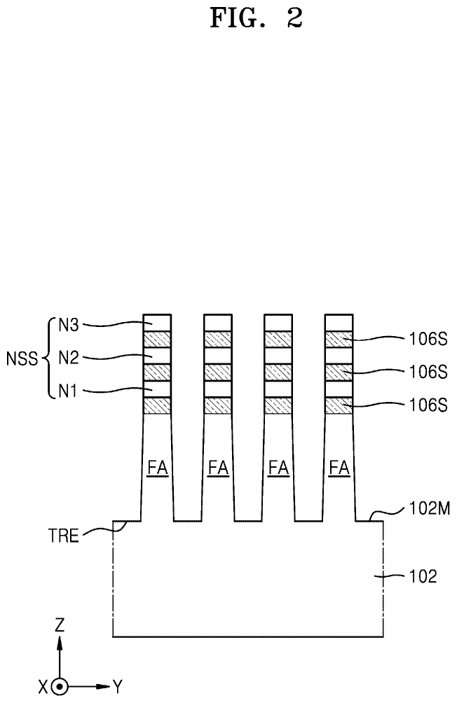

In FIG. 2, a stacked structure of the plurality of sacrificial semiconductor layers 106S and the plurality of nanosheet semiconductor layers NS and part of an upper side of the substrate 102 may be etched to form a plurality of trenches TRE. A plurality of fin-type active areas FA defined by the plurality of trenches TRE may be formed. The plurality of fin-type active areas FA may extend parallel to each other in a first horizontal direction (X direction). The plurality of fin-type active areas FA may protrude upward from a main surface 102M of the substrate 102 in a vertical direction (Z direction). The plurality of fin-type active areas FA may be arranged at a constant pitch in a second horizontal direction (Y direction).

The plurality of sacrificial semiconductor layers 106S and a plurality of nanosheet stacked structures NSS may be disposed on the plurality of fin-type active areas FA. The plurality of nanosheet stacked structures NSS may include a plurality of nanosheets N1, N2, and N3. The plurality of nanosheets N1, N2, and N3 may include a first nanosheet N1, a second nanosheet N2, and a third nanosheet N3 that are arranged to be sequentially spaced apart in the vertical direction (Z direction) from the bottom to the top. However, this is only an example, and the present disclosure is not limited thereto. For example, the nanosheet stacked structure NSS may include four or more nanosheets. Herein, for convenience of description, the first nanosheet N1 and the third nanosheet N3 are described as respectively the lowermost nanosheet and the uppermost nanosheet from among the plurality of nanosheets N1, N2, and N3 included in the nanosheet stacked structure NSS.

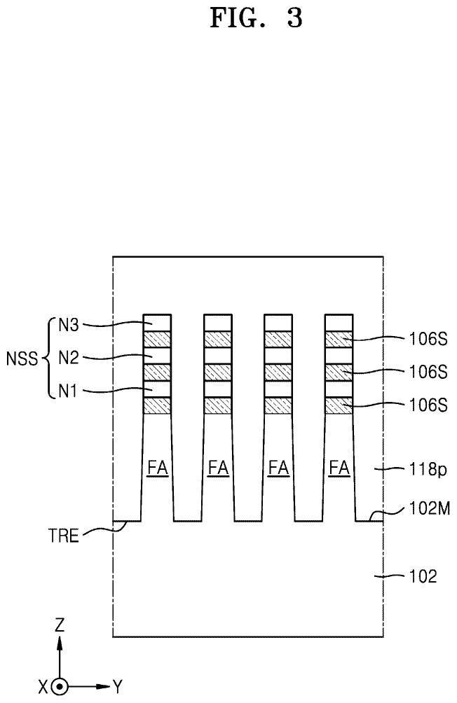

In FIG. 3, a preliminary device isolation film 118p covering the plurality of fin-type active areas FA, the plurality of sacrificial semiconductor layers 106S, and the plurality of nanosheet stacked structures NSS and filling in the plurality of trenches TRE may be formed. The preliminary device isolation film 118p may be formed to cover a side surface of the plurality of fin-type active areas FA, a side surface of the plurality of sacrificial semiconductor layers 106S, and a side surface and an upper surface of the plurality of nanosheet stacked structures NSS. For example, the preliminary device isolation film 118p may include a material including at least one of silicon oxide, silicon nitride, and silicon oxynitride. The preliminary device isolation film 118p may include a single layer including one type of insulating film, a double layer including two types of insulating films, or a multi-layer including a combination of at least three types of insulating films. For example, the preliminary device isolation film 118p may include two different types of insulating films. For example, the preliminary device isolation film 118p may include a silicon oxide film and a silicon nitride film. For example, the preliminary device isolation film 118p may include a triple layer of a silicon oxide film, a silicon nitride film, and a silicon oxide film.

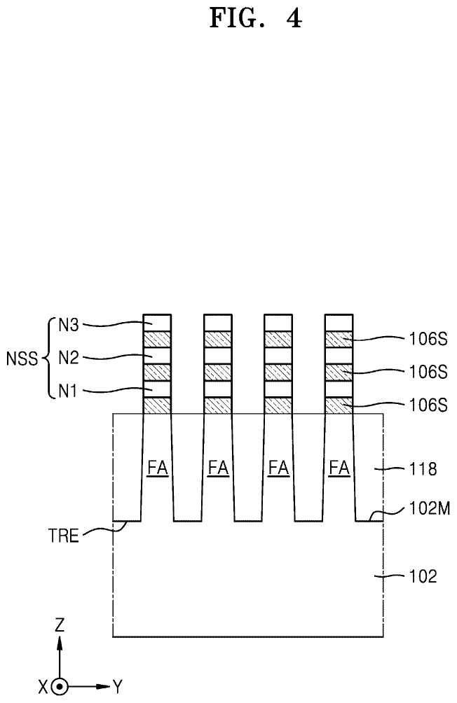

In FIGS. 3 and 4, a device isolation film 118 may be formed by performing a recess process for removing the preliminary device isolation film 118p to a certain thickness from an upper portion thereof. To perform this recess process, a dry etching, a wet etching, or a combination of dry etching and wet etching may be used.

The recess process may be performed so that an upper surface of the device isolation film 118 is at the same or substantially similar level to an upper surface of the fin-type active area FA. As a result, the upper and side surfaces of the plurality of nanosheet stacked structures NSS on the plurality of fin-type active areas FA and side surfaces of the plurality of sacrificial semiconductor layers 106S may be exposed.

In FIGS. 5A and 5B, a plurality of dummy gate structures DGS extending and crossing at least part of the plurality of fin-type active areas FA may be formed over the plurality of fin-type active areas FA on which the plurality of nanosheet stacked structures NSS and the plurality of sacrificial semiconductor layers 106S are formed. The plurality of dummy gate structures DGS may extend in parallel to each other in the second horizontal direction (Y direction).

The dummy gate structure DGS may have a structure in which an oxide film D12, a dummy gate layer D14, and a capping layer D16 are sequentially stacked. In an example of forming the dummy gate structure DGS, the oxide film D12, the dummy gate layer D14, and the capping layer D16 are sequentially formed to cover an exposed surface of the plurality of fin-type active areas FA, an exposed surface of the plurality of sacrificial semiconductor layers 106S, and an upper surface of the device isolation film 118, respectively, and then may be patterned so as to remain only in portions in which the oxide film D12, the dummy gate layer D14, and the capping layer D16 are necessary.

The oxide film D12 may be formed by a thermal oxidation, atomic layer deposition (ALD), chemical vapor deposition (CVD), physical vapor deposition (PVD), metal organic ALD (MOALD), or metal organic CVD (MOCVD) process. Each of the dummy gate layer D14 and the capping layer D16 may be formed by an ALD, CVD, PVD, MOALD, or MOCVD process. In some implementations, the dummy gate layer D14 may include polysilicon and the capping layer D16 may include a silicon nitride film. However, the present disclosure is not limited thereto.

Thereafter, a gate spacer 130 covering opposite side surfaces of the dummy gate structure DGS may be formed. In order to form the gate spacer 130, a spacer layer is formed on the semiconductor substrate 102 on which the dummy gate structure DGS is formed, and then, the spacer layer may be etched back again so that the gate spacer 130 remains. The gate spacer 130 may include, for example, a silicon nitride film.

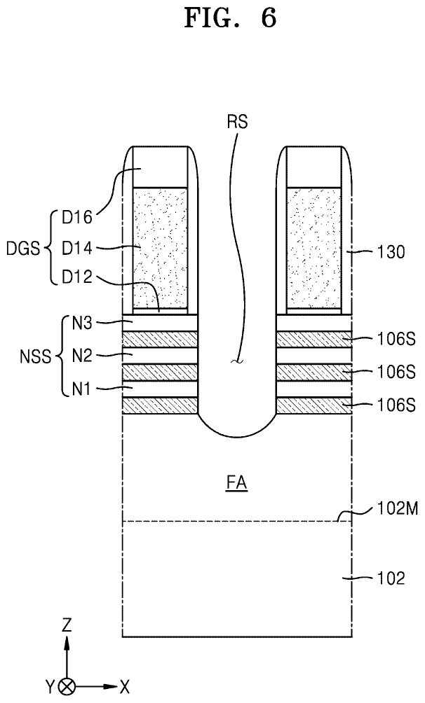

In FIG. 6, the dummy gate structure DGS and the gate spacer 130 may be used as an etch mask to form a recess space RS by removing part of the plurality of nanosheet stacked structures NSS and part of the plurality of sacrificial semiconductor layers 106S through etching. The fin-type active area FA may be exposed on a lower surface of the recess space RS. In some implementations, in a process of etching part of the plurality of nanosheet stacked structures NSS and part of the plurality of sacrificial semiconductor layers 106S, an upper portion of the fin-type active area FA may also be removed.

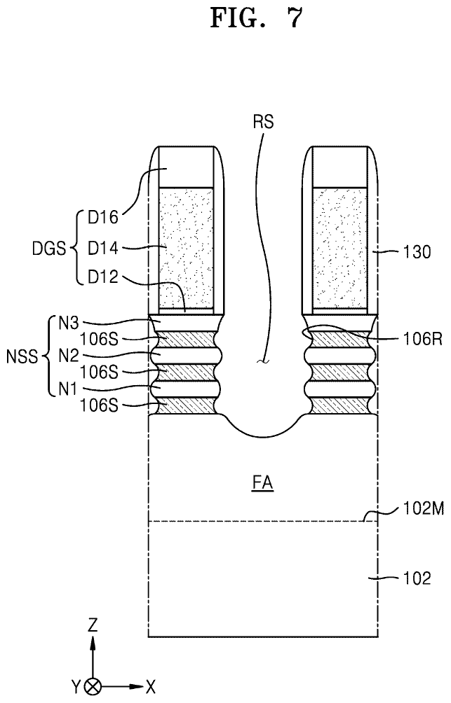

In FIGS. 6 and 7, while part of the plurality of nanosheet stacked structures NSS and part of the plurality of sacrificial semiconductor layers 106S are etched, an etching condition may be controlled so that an etching amount of the plurality of sacrificial semiconductor layers 106S is greater than an etching amount of the plurality of nanosheet stacked structures NSS, and side surfaces of the plurality of sacrificial semiconductor layers 106S are recessed more than side surfaces of the plurality of nanosheet stacked structures NSS, thereby forming a plurality of sacrificial recesses 106R.

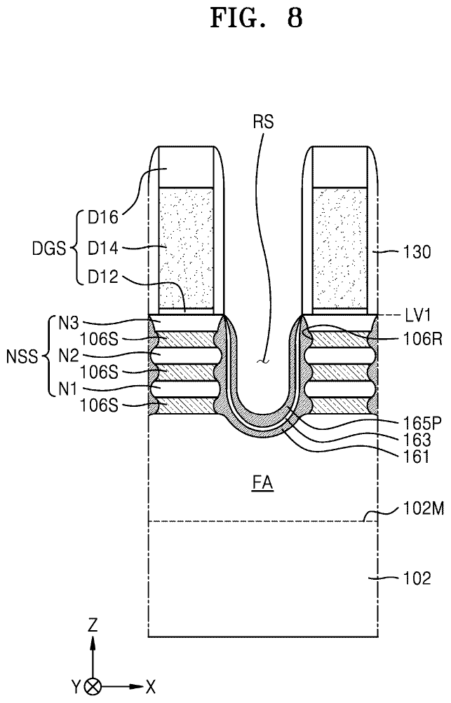

In FIG. 8, a first source/drain layer 161, a second source/drain layer 163, and a preliminary source/drain layer 165P may be sequentially formed in the recess space RS. The first source/drain layer 161 may be formed to cover lower and side surfaces of the recess space RS while filling in the plurality of sacrificial recesses 106R, the second source/drain layer 163 may be formed to cover a surface of the first source/drain layer 161, and the preliminary source/drain layer 165P may be formed to cover a surface of the second source/drain layer 163. The second source/drain layer 163 may be located between the first source/drain layer 161 and the preliminary source/drain layer 165P. In some implementations, an uppermost end of each of the first source/drain layer 161, the second source/drain layer 163, and the preliminary source/drain layer 165P may be at a first vertical level LV1. For example, an upper surface of the third nanosheet N3, which is the uppermost nanosheet of the plurality of nanosheets N1, N2, and N3, may be at the first vertical level LV1.

The first source/drain layer 161 may be formed by using an epitaxial growth process from the fin-type active area FA, which is exposed within the plurality of sacrificial recesses 106R and the recess space RS, and the plurality of nanosheets N1, N2, and N3. The second source/drain layer 163 may be formed by using an epitaxial growth process from the first source/drain layer 161. The preliminary source/drain layer 165P may be formed by using an epitaxial growth process from the second source/drain layer 163. A growth temperature of the second source/drain layer 163 may be higher than a growth temperature of each of the first source/drain layer 161 and the preliminary source/drain layer 165P. For example, the growth temperature of the second source/drain layer 163 may be about 5° C. to about 15° C. higher than the growth temperature of each of the first source/drain layer 161 and the preliminary source/drain layer 165P. For example, the growth temperature of the second source/drain layer 163 may be about 679° C. to about 688° C., and the growth temperature of each of the first source/drain layer 161 and the preliminary source/drain layer 165P may be about 669° C. to about 678° C.

The second source/drain layer 163 may include a material that is different from a material of each of the first source/drain layer 161 and the preliminary source/drain layer 165P. In some implementations, the first source/drain layer 161 and the preliminary source/drain layer 165P may include the same material. For example, the second source/drain layer 163 may include Si but not Ge. In some implementations, the second source/drain layer 163 may include Si that is not doped with impurities. In some implementations, the second source/drain layer 163 may include Si doped with an impurity such as boron (B). Each of the first source/drain layer 161 and the preliminary source/drain layer 165P may include SiGe. In some implementations, each of the first source/drain layer 161 and the preliminary source/drain layer 165P may include SiGe having a relatively low Ge content ratio. For example, each of the first source/drain layer 161 and the preliminary source/drain layer 165P may include SiGe having a Ge content ratio greater than 0% and less than or equal to about 10%. The Ge content ratio of each of the first source/drain layer 161 and the preliminary source/drain layer 165P may be referred to as a first Ge content ratio.

The first source/drain layer 161 may be in contact with an upper surface of the fin-type active area FA and a side surface of one end of the plurality of nanosheets N1, N2, and N3. The first source/drain layer 161 may be formed to have a thickness of about 2 nm to about 5 nm on the fin-type active area FA and side surfaces of the plurality of nanosheets N1, N2, and N3. The second source/drain layer 163 may be formed to have a thickness of about 0.5 nm to about 1.5 nm. The preliminary source/drain layer 165P may be formed to have a thickness of about 3 nm to about 6 nm.

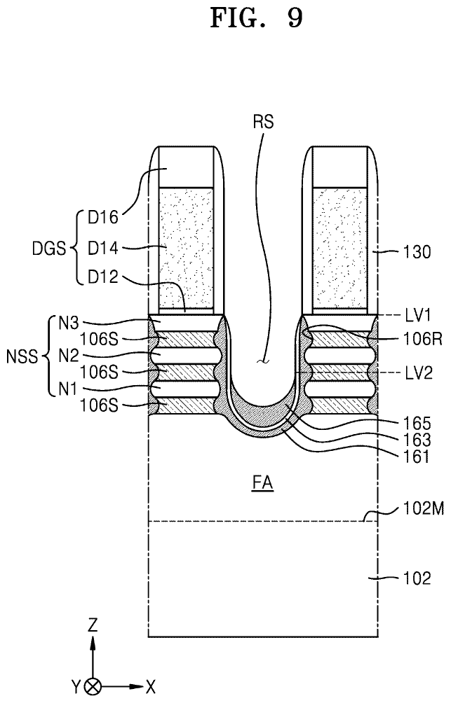

In FIGS. 8 and 9, a third source/drain layer 165 may be formed by reflowing the preliminary source/drain layer 165P. The third source/drain layer 165 formed by reflowing the preliminary source/drain layer 165P may have a thickness of about 6 nm to about 12 nm. An upper surface of the third source/drain layer 165 may have a concave shape. The growth temperature of the second source/drain layer 163 is higher than the growth temperatures of the first source/drain layer 161 and the preliminary source/drain layer 165P, and while the preliminary source/drain layer 165P is reflown, the first source/drain layer 161 covered by the second source/drain layer 163 may maintain the shape thereof without reflowing. The second source/drain layer 163 may perform a function of a reflow stopper layer for preventing reflow of the first source/drain layer 161.

An uppermost end of the third source/drain layer 165 formed by reflowing the preliminary source/drain layer 165P may be at a second vertical level LV2, which is lower than the first vertical level LV1. The second vertical level LV2 may be lower than an uppermost end of the nanosheet stacked structure NSS and higher than a lowermost end of the nanosheet stacked structure NSS.

For example, the second vertical level LV2 may be lower than the upper surface of the third nanosheet N3, which is the uppermost nanosheet from among the plurality of nanosheets N1, N2, and N3, and may be higher than a lower surface of the first nanosheet N1, which is the lowermost nanosheet from among the plurality of nanosheets N1, N2, and N3.

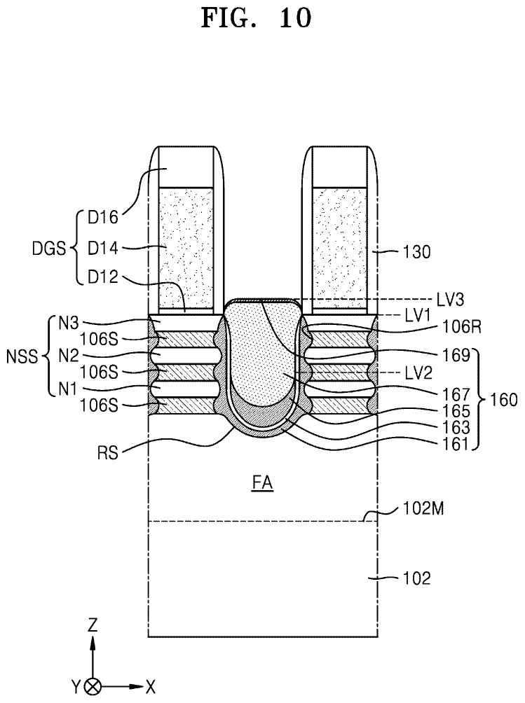

In FIG. 10, a fourth source/drain layer 167 and a source/drain capping layer 169 may be sequentially formed on the third source/drain layer 165 to form a plurality of source/drain regions 160, which respectively include the first source/drain layer 161, the second source/drain layer 163, the third source/drain layer 165, the fourth source/drain layer 167, and the source/drain capping layer 169. The fourth source/drain layer 167 may be formed by using an epitaxial growth process from the second source/drain layer 163 and the third source/drain layer 165. The fourth source/drain layer 167 may cover the second source/drain layer 163 and the third source/drain layer 165. The fourth source/drain layer 167 may be formed to fill in the recess space RS. An upper surface of the fourth source/drain layer 167 may protrude from the recess space RS and may have a convex shape. The source/drain capping layer 169 may be formed by using an epitaxial growth process from the fourth source/drain layer 167. The source/drain capping layer 169 may be formed to cover the upper surface of the fourth source/drain layer 167.

The fourth source/drain layer 167 may include SiGe. In some implementations, the fourth source/drain layer 167 may include SiGe having a relatively high Ge content ratio. For example, the fourth source/drain layer 167 may include SiGe having a Ge content ratio of about 40% to about 60%. The Ge content ratio of the fourth source/drain layer 167 may be referred to as a second Ge content ratio. The source/drain capping layer 169 may include Si or SiGe. In some implementations, the source/drain capping layer 169 may include Si doped with an impurity such as boron (B). When each of the second source/drain layer 163 and the source/drain capping layer 169 includes Si doped with an impurity such as B, the concentration of the impurity included in the second source/drain layer 163 may be higher than the concentration of the impurity included in the source/drain capping layer 169. In some implementations, the source/drain capping layer 169 may have a higher Ge content ratio than each of the first source/drain layer 161 and the third source/drain layer 165 and may include SiGe having a relatively low Ge content ratio compared to the fourth source/drain layer 167. For example, the source/drain capping layer 169 may include SiGe having a Ge content ratio that is greater than about 20% and less than about 40%. The Ge content ratio of the source/drain capping layer 169 may be referred to as a third Ge content ratio.

The fourth source/drain layer 167 may be formed such that a vertical level of an uppermost end of the fourth source/drain layer 167 is higher than the first vertical level LV1. The source/drain capping layer 169 may be formed to have a thickness of about 1 nm to about 2 nm. An uppermost end of the source/drain region 160, that is, an uppermost end of the source/drain capping layer 169, may be at a third vertical level LV3 that is higher than the first vertical level LV1.

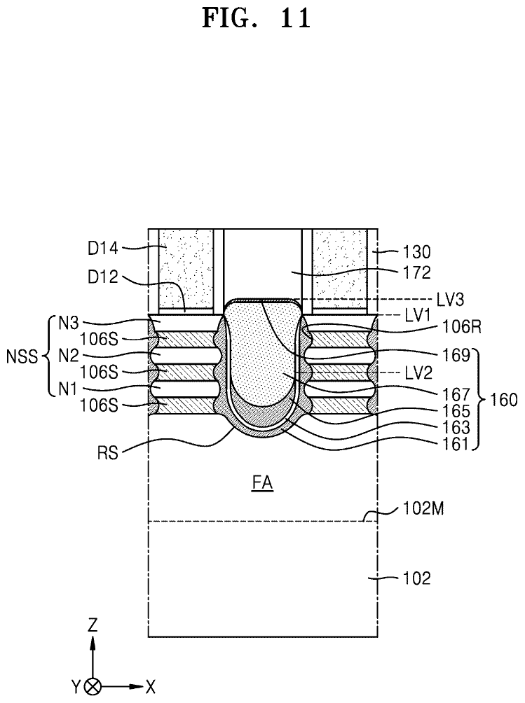

In FIGS. 10 and 11, after an inter-gate insulating film 172 is formed on the plurality of dummy gate structures DGS and the plurality of source/drain regions 160, the inter-gate insulating film 172 may be planarized to remove the capping layer D16 covering an upper surface of the dummy gate layer D14, and the gate spacer 130, which is around the capping layer D16, and the inter-gate insulating film 172 may be polished to a certain thickness from the upper surfaces thereof so that the upper surface of the inter-gate insulating film 172 is at approximately the same level as the upper surface of the dummy gate layer D14. In some implementations, the inter-gate insulating film 172 may include a silicon oxide film.

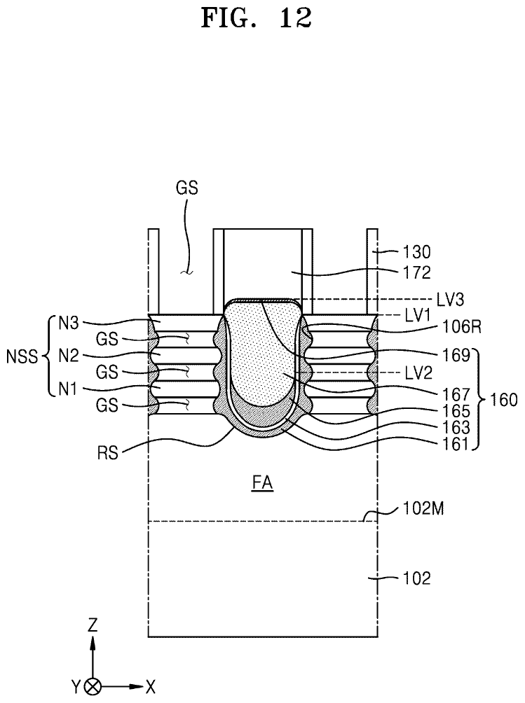

In FIGS. 11 and 12, a plurality of gate spaces GS may be formed by removing the dummy gate layer D14, which is exposed through the inter-gate insulating film 172 and the gate spacer 130, and the oxide film D12 thereunder and by removing the plurality of sacrificial semiconductor layers 106S. Surfaces of the plurality of nanosheets N1, N2, and N3 and part of the upper surface of the fin-type active area FA may be exposed through the gate spaces GS. In some implementations, part of the plurality of sacrificial semiconductor layers 106S may remain without being removed. In some implementations, the dummy gate layer D14 and the oxide film D12 may be removed by performing a wet etching process. To perform wet etching, for example, an etchant including nitric acid (HNO₃), diluted fluoric acid (DHF), ammonium hydroxide (NH₄OH), tetramethyl ammonium hydroxide (TMAH), potassium hydroxide (KOH), or a combination thereof may be used.

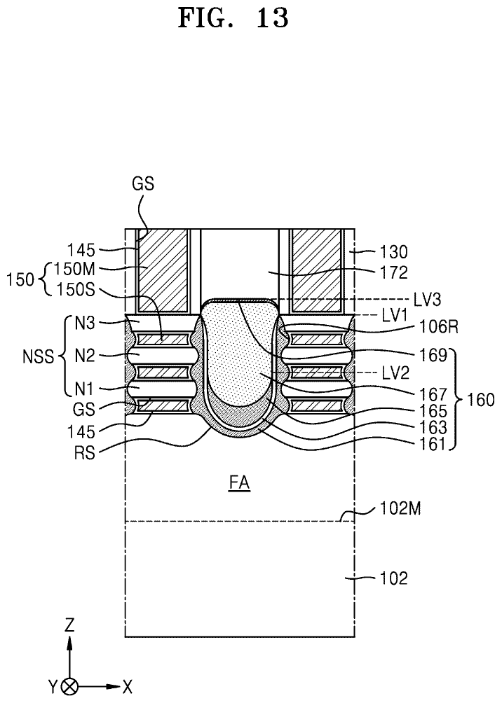

In FIG. 13, a plurality of gate dielectric films 145 may be formed on surfaces exposed in the plurality of gate spaces GS, and a plurality of gate electrodes 150 filling in the plurality of gate spaces GS may be formed on the plurality of gate dielectric films 145. For example, the plurality of gate dielectric films 145 may be formed to cover surfaces of the plurality of nanosheets N1, N2, and N3 exposed in the plurality of gate spaces GS, part of the upper surface of the fin-type active area FA, and surfaces of the plurality of source/drain regions 160. The plurality of gate electrodes 150 may extend in parallel with each other in the second horizontal direction (Y direction). For example, the plurality of gate dielectric films 145 and the plurality of gate electrodes 150 may be formed by a replacement metal gate (RMG) process.

The gate dielectric film 145 may include a silicon oxide film, a high-k dielectric film, or a combination thereof. In some implementations, the gate dielectric film 145 may include a stacked structure of an interfacial layer and a high-k dielectric film. The interfacial layer may include a low dielectric material with a dielectric constant of about 9 or less. For example, the interfacial layer may include an oxide, a nitride, or an oxynitride. The high-k dielectric film may include a metal oxide or a metal oxynitride. The high-k dielectric film may include a material with a higher dielectric constant than the silicon oxide film. For example, the high-k dielectric film may have a dielectric constant of about 10 to about 25. The high-k dielectric film may include a material selected from hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, and a combination thereof. However, a material included in the high-k dielectric film is not limited thereto. The high-k dielectric film may be formed by an ALD, CVD, or PVD process. The high-k dielectric film may have a thickness of about 10 Å to about 40 Å, but is not limited thereto. In some implementations, the interfacial layer may be omitted. For example, the gate dielectric film 145 may include hafnium oxide (HfO₂), aluminum oxide (Al₂O₃), hafnium aluminum oxide (HfAlO₃), tantalum oxide (Ta₂O₃), or titanium dioxide (TiO₂).

In some implementations, the gate dielectric film 145 may include a ferroelectric material film with ferroelectric properties or a paraelectric material film with paraelectric properties. For example, the gate dielectric film 145 may include one ferroelectric material film. For example, the gate dielectric film 145 may include a plurality of ferroelectric material films spaced apart from each other. For example, the gate dielectric film 145 may have a stacked-layer structure in which a plurality of ferroelectric material films and a plurality of paraelectric material films are alternately stacked.

The ferroelectric material film may have a negative capacitance, and the paraelectric material film may have a positive capacitance. For example, when two or more capacitors are connected in series and a capacitance of each of the capacitors has a positive value, the total capacitance is less than the capacitance of each individual capacitor. On the other hand, when at least one of two capacitors connected in series has a negative value, the total capacitance may have a positive value and be greater than the absolute value of each individual capacitance.

When a ferroelectric material film with a negative capacitance and a paraelectric material film with a positive capacitance are connected in series, the total capacitance value of the ferroelectric material film and the paraelectric material film connected in series may increase. By taking advantage of the increase in overall capacitance value, a transistor including a ferroelectric material film may have a subthreshold swing (SS) of less than about 60 mV/decade.

The ferroelectric material film may have ferroelectric properties. For example, the ferroelectric material film may include at least one of hafnium oxide, hafnium zirconium oxide, barium strontium titanium oxide, barium titanium oxide, and lead zirconium titanium oxide. Here, for example, hafnium zirconium oxide may be a material in which zirconium (Zr) is doped into hafnium oxide. In another example, hafnium zirconium oxide may be a compound of hafnium (Hf), Zr, and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). Depending on a ferroelectric material included in a ferroelectric material film, the type of dopant included in the ferroelectric material film may vary. When the ferroelectric material film includes hafnium oxide, the dopant included in the ferroelectric material film may include, for example, at least one of Gd, Si, Zr, Al, and Y. When the dopant is Al, the ferroelectric material film may include Al of about 3 atomic % (at %) to about 8 at %. Here, a ratio of the dopant may be a ratio of Al to the sum of hafnium and Al. When the dopant is Si, the ferroelectric material film may include Si of about 2 at % to about 10 at %. When the dopant is Y, the ferroelectric material film may include Y of about 2 at % to about 10 at %. When the dopant is Gd, the ferroelectric material film may include Gd of about 1 at % to about 7 at %. When the dopant is Zr, the ferroelectric material film may include Zr of about 50 at % to about 80 at %.

The paraelectric material film may have paraelectric properties. The paraelectric material film may include, for example, at least one of silicon oxide and a metal oxide having a high dielectric constant. The metal oxide included in the paraelectric material film may include, for example, at least one of hafnium oxide, zirconium oxide, and aluminum oxide, but is not limited thereto.

The ferroelectric material film and the paraelectric material film may include the same material. The ferroelectric material film may have ferroelectric properties, but the paraelectric material film may not have ferroelectric properties. For example, when the ferroelectric material film and the paraelectric material film include hafnium oxide, a crystalline structure of hafnium oxide included in the ferroelectric material film may be different from a crystalline structure of hafnium oxide included in the paraelectric material film.

The ferroelectric material film may have a thickness having ferroelectric properties. The thickness of the ferroelectric material film may be, for example, about 0.5 nm to about 10 nm, but is not limited thereto. Because a threshold thickness representing ferroelectric properties may vary for each ferroelectric material, the thickness of the ferroelectric material film may vary depending on the ferroelectric material.

The gate electrode 150 may include a metal-containing layer for adjusting a work function and a metal-containing layer for gap filling that fills in an upper surface of the metal-containing layer for adjusting a work function. The metal-containing layer for adjusting a work function may include at least one metal selected from titanium (Ti), tungsten (W), ruthenium (Ru), Nb, molybdenum (Mo), Hf, nickel (Ni), cobalt (Co), platinum (Pt), ytterbium (Yb), terbium (Tb), Dy, Er, and palladium (Pd). In some implementations, the gate electrode 150 may have a structure in which a metal nitride layer, a metal layer, a conductive capping layer, and a gap-fill metal film are sequentially stacked. The metal nitride layer and the metal layer may include at least one metal selected from Ti, tantalum (Ta), W, Ru, Nb, Mo, and Hf. The gap-fill metal film may include a W film or an Al film. In some embodiments, the gate electrode 150 may include a stacked structure of TiAlC/TiN/W, a stacked structure of TiN/TaN/TiAlC/TiN/W, or a stacked structure of TiN/TaN/TiN/TiAlC/TiN/W, but is not limited thereto.

The gate electrode 150 may include a main gate portion 150M that covers an upper surface of the nanosheet stacked structure NSS including the plurality of nanosheets N1, N2, and N3, and a plurality of sub-gate portions 150S connected to the main gate portion 150M and formed in a space between each of the plurality of nanosheets N1, N2, and N3 and the fin-type active area FA.

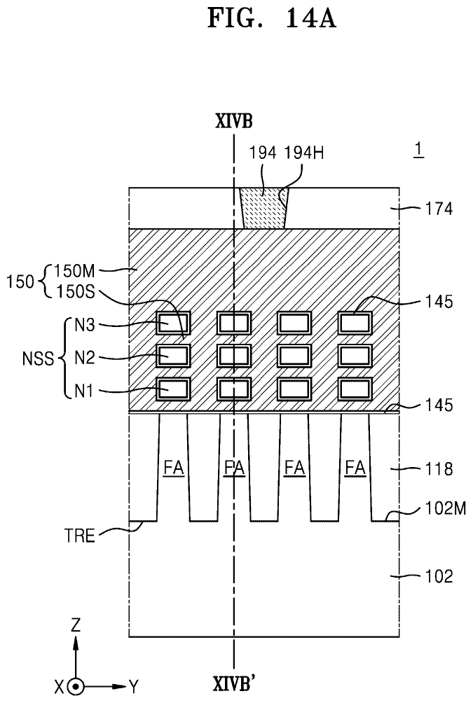

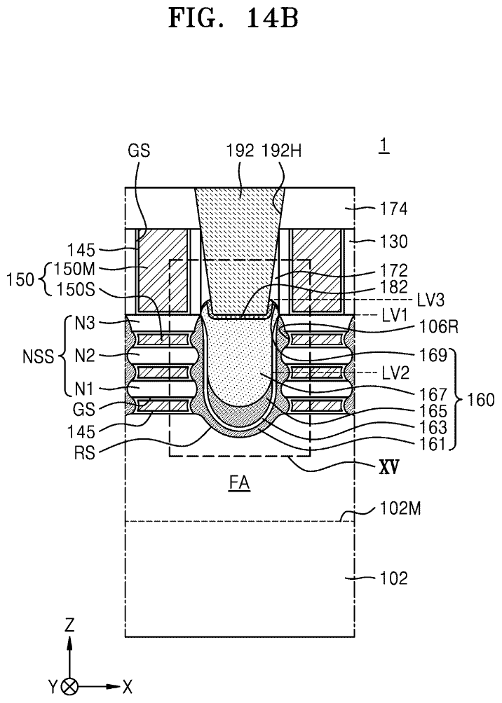

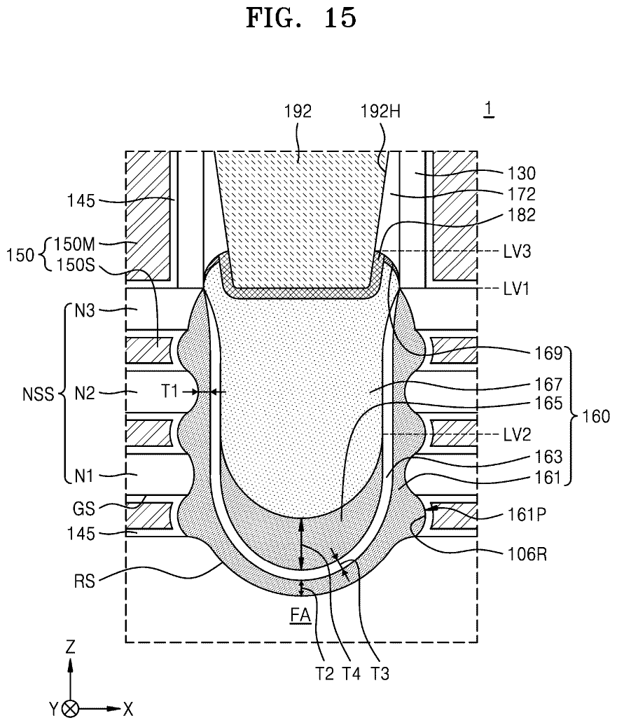

FIGS. 14A, 14B, and 15 are cross-sectional views of an example of an integrated circuit device according to some implementations. FIG. 14A is a Y-Z vertical cross-sectional view, and FIGS. 14B and 15 are X-Z vertical cross-sectional views, wherein FIG. 14B is a cross-sectional view taken along line XIVB-XIVB′ of FIG. 14A, and FIG. 15 is an enlarged cross-sectional view of region XV of FIG. 14B.

In FIGS. 14A and 14B, an interlayer insulating film 174 covering the plurality of gate electrodes 150 and the inter-gate insulating film 172 may be formed. For example, the interlayer insulating film 174 may include silicon oxide or an insulating material having a lower dielectric constant than silicon oxide. In some implementations, the interlayer insulating film 174 may include a tetraethyl orthosilicate (TEOS) film or an ultra-low K (ULK) film having an ultra-low dielectric constant K of about 2.2 to about 2.4. The ULK film may include a silicon oxycarbide (SiOC) film or a SiCOH film. The interlayer insulating film 174 and the inter-gate insulating film 172 may be partially etched to form a first contact hole 192H exposing the source/drain region 160. A metal silicide film 182 may be formed on an upper surface of the source/drain region 160 exposed through the first contact hole 192H. The metal silicide film 182 may include tungsten silicide (WSi), titanium silicide (TiSi), cobalt silicide (CoSi), or nickel silicide (NiSi).

In addition, the interlayer insulating film 174 may be partially etched to form a second contact hole 194H exposing an upper surface of the gate electrode 150, that is, an upper surface of the main gate portion 150M. In some implementations, the first contact hole 192H and the second contact hole 194H may be formed together through a single etching process. However, the present disclosure is not limited thereto, and the first contact hole 192H and the second contact hole 194H may each be formed through a separate etching process. In some implementation, the first contact hole 192H may extend into the source/drain region 160. For example, the first contact hole 192H may pass through the source/drain capping layer 169 and extend into the fourth source/drain layer 167, and the metal silicide film 182 may be in contact with the fourth source/drain layer 167.

Thereafter, an integrated circuit device 1 may be formed by forming a first contact plug 192 filling in the first contact hole 192H and a second contact plug 194 filling in the second contact hole 194H. The first contact plug 192 may be connected to the source/drain region 160 through the metal silicide film 182, and the second contact plug 194 may be connected to the gate electrode 150. In some implementations, the first contact plug 192 and the second contact plug 194 may be formed together. However, the present disclosure is not limited thereto, and the first contact plug 192 and the second contact plug 194 may each be formed through a separate process. Each of the first contact plug 192 and the second contact plug 194 may include a metal material, such as W, Al, Cu, Ti, Ta, Ru, manganese (Mn), or Co, a metal nitride, such as TiN, TaN, CoN, or WN, or an alloy, such as cobalt tungsten phosphide (CoWP), cobalt tungsten boron (CoWB), or cobalt tungsten boron phosphide (CoWBP). In some implementations, at least part of the first contact plug 192 and the second contact plug 194 may include a conductive barrier layer and a conductive core layer that covers the conductive barrier layer. The conductive barrier layer may include Ti, Ta, TiN, TaN, or a combination thereof, and the conductive core layer may include Co, W, Cu, Ru, iridium (Ir), Mo, or a combination thereof. In a plan view, each of the first contact plug 192 and the second contact plug 194 may have a circular shape, an elliptical shape, or a polygonal shape and may have a vertical pillar shape extending in the vertical direction (Z direction).

The integrated circuit device 1 may be a logic semiconductor chip. For example, the integrated circuit device 1 may be a central processing unit (CPU) chip, a graphics processing unit (GPU) chip, or an application processor (AP) chip. Herein, the logic semiconductor chip does not refer to a memory semiconductor chip but refers to a semiconductor chip that performs logical operations. For example, the logic semiconductor chip may include a logic cell. In some implementations, the logic semiconductor chip may include a logic cell and a memory cell together. The logic cell may include a plurality of circuit elements, such as transistors and resistors, and may be configured in various ways. The logic cell may configure, for example, an AND, a NAND, an OR, a NOR, an exclusive OR (XOR), an exclusive NOR (XNOR), an inverter (INV), an adder (ADD), a buffer (BUF), delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, or a latch, and the logic cell may configure standard cells that perform a desired logical function, such as counters.

The integrated circuit device 1 may include the fin-type active area FA protruding upward from the main surface 102M of the substrate 102 in the vertical direction (Z direction) and extending in the first horizontal direction (X direction), and the plurality of nanosheet stacked structures NSS facing the upper surface of the fin-type active area FA at a position spaced apart from the upper surface of the fin-type active area FA so that a multi-gate MOSFET may be provided. In some implementations, the integrated circuit device 1 may include a multi-gate PMOS.

The plurality of trenches TRE defining the plurality of fin-type active areas FA may be formed in the substrate 102. The side surfaces of the plurality of fin-type active areas FA may be covered by the device isolation film 118 filling in the plurality of trenches TRE. A level of the upper surface of the fin-type active area FA and a level of the upper surface of the device isolation film 118 may be identical or similar to each other.

The plurality of nanosheet stacked structures NSS may be spaced apart from the upper surface of the fin-type active area FA. The plurality of nanosheet stacked structures NSS may include the plurality of nanosheets N1, N2, and N3 that extend in parallel with the upper surface of the fin-type active area FA on the substrate 102.

The plurality of nanosheets N1, N2, and N3 forming one nanosheet stacked structure NSS may be sequentially stacked one by one on the upper surface of the fin-type active area FA. In this example, one nanosheet stacked structure NSS includes three nanosheets N1, N2, and N3. However, the present disclosure is not limited thereto. Each of the plurality of nanosheets N1, N2, and N3 may have a channel region. In some embodiments, the plurality of nanosheets N1, N2, and N3 may include the same material as the substrate 102.

On the fin-type active area FA, the plurality of gate electrodes 150 may extend in the second horizontal direction (Y direction that crosses the first horizontal direction (X direction)). The plurality of gate electrodes 150 may at least partially overlap each of the plurality of nanosheet stacked structures NSS in the vertical direction (Z direction). Each of the plurality of gate electrodes 150 may surround the nanosheet stacked structure NSS. For example, each of the plurality of gate electrodes 150 may be formed to surround at least part of the plurality of nanosheets N1, N2, and N3 and cover the nanosheet stacked structure NSS. The gate electrode 150 may include the main gate portion 150M covering the upper surface of the nanosheet stacked structure NSS, and the plurality of sub-gate portions 150S connected to the main gate portion 150M and formed in a space between the fin-type active area FA and the plurality of nanosheets N1, N2, and N3, that is, on the lower side of each of the plurality of nanosheets N1, N2, and N3. The gate dielectric film 145 may be formed between the nanosheet stacked structure NSS and the gate electrode 150 and between the fin-type active area FA and the gate electrode 150. The gate dielectric film 145 may surround the gate electrode 150.

Between the fin-type active area FA and the nanosheet stacked structure NSS, that is, between the fin-type active area FA and the first nanosheet N1, and between the plurality of nanosheets N1, N2, and N3 adjacent to each other in the vertical direction (Z direction), that is, between the first nanosheet N1 and the second nanosheet N2 and between the second nanosheet N2 and the third nanosheet N3, the plurality of sacrificial recesses 106R not filled with the gate dielectric film 145 and the gate electrode 150 may be defined.

The plurality of source/drain regions 160 may be formed on the plurality of fin-type active areas FA. Each of the plurality of source/drain regions 160 may be connected to one end of each of the plurality of nanosheets N1, N2, and N3 adjacent thereto.

The gate spacer 130 sequentially covering a side surface of the gate electrode 150 may be formed on the plurality of nanosheet stacked structures NSS. The gate spacer 130 may include a silicon nitride film, but is not limited thereto. The gate spacer 130 may cover a side surface of the main gate portion 150M within the gate electrode 150.

The inter-gate insulating film 172 and the interlayer insulating film 174 may be sequentially formed on the plurality of source/drain regions 160. Each of the inter-gate insulating film 172 and the interlayer insulating film 174 includes a silicon oxide film, but is not limited thereto.

A plurality of first contact plugs 192 may be connected to the plurality of source/drain regions 160. The first contact plug 192 may pass through the interlayer insulating film 174 and the inter-gate insulating film 172 and be connected to the source/drain region 160. The metal silicide film 182 may be located between the source/drain region 160 and the first contact plug 192. In some embodiments, the metal silicide film 182 may be omitted. A plurality of second contact plugs 194 may be connected to the plurality of gate electrodes 150. The second contact plug 194 may pass through the interlayer insulating film 174 and be connected to the gate electrode 150. Each of the first contact plug 192 and the second contact plug 194 may include metal, conductive metal nitride, or a combination thereof.

Each of the plurality of source/drain regions 160 may include the first source/drain layer 161, the second source/drain layer 163, the third source/drain layer 165, the fourth source/drain layer 167, and the source/drain capping layer 169.

The first source/drain layer 161 may be connected to the plurality of nanosheets N1, N2, and N3. In some embodiments, the first source/drain layer 161 may include a plurality of protrusions 161P protruding toward the plurality of sub-gate portions 150S and filling in the plurality of sacrificial recesses 106R. The plurality of protrusions 161P may face the plurality of sub-gate portions 150S with the gate dielectric film 145 therebetween. The first source/drain layer 161 may have a first thickness T1 on side surfaces of the plurality of nanosheets N1, N2, and N3 and may have a second thickness T2 on the fin-type active area FA. The first thickness T1 and the second thickness T2 may have substantially the same value. For example, each of the first thickness T1 and the second thickness T2 may be about 2 nm to about 5 nm. The first source/drain layer 161 may include SiGe. The first source/drain layer 161 may include SiGe having a relatively low Ge content ratio. For example, the first source/drain layer 161 may include SiGe having a Ge content ratio that is greater than 0% and about 10% or less.

The second source/drain layer 163 may have a third thickness T3 on the first source/drain layer 161. The third thickness T3 may have a smaller value than each of the first thickness T1 and the second thickness T2. For example, the third thickness T3 may be about 0.5 nm to about 1.5 nm. The second source/drain layer 163 may include a material that is different from a material of each of the first source/drain layer 161 and the third source/drain layer 165. For example, the second source/drain layer 163 may include Si but not Ge. In some implementations, the second source/drain layer 163 may include Si that is not doped with impurities. In some implementations, the second source/drain layer 163 may include Si doped with an impurity such as B.

The third source/drain layer 165 may cover part of the second source/drain layer 163. For example, the third source/drain layer 165 may cover part of a lower side of the second source/drain layer 163. The third source/drain layer 165 may have a fourth thickness T4 in the vertical direction (Z direction) based on the bottom surface of the source/drain region 160. The fourth thickness T4 may have a greater value than each of the first thickness T1, the second thickness T2, and the third thickness T3. For example, the fourth thickness T4 may be about 6 nm to about 12 nm. In some embodiments, the third source/drain layer 165 may include the same material as the first source/drain layer 161. The third source/drain layer 165 may include SiGe. The third source/drain layer 165 may include SiGe having a relatively low Ge content ratio. For example, the third source/drain layer 165 may include SiGe having a Ge content ratio that is greater than 0% and about 10% or less. In some implementations, each of the first source/drain layer 161 and the third source/drain layer 165 may include SiGe having the same Ge content ratio.

An uppermost end of each of the first source/drain layer 161 and the second source/drain layer 163 may be at the first vertical level LV1. For example, the upper surface of the third nanosheet N3, which is the uppermost nanosheet of the plurality of nanosheets N1, N2, and N3, may be at the first vertical level LV1. The uppermost end of the third source/drain layer 165 may be at the second vertical level LV2 that is lower than the first vertical level LV1. The second vertical level LV2 may be lower than the uppermost end of the nanosheet stacked structure NSS and higher than the lowermost end of the nanosheet stacked structure NSS. For example, the second vertical level LV2 may be lower than the upper surface of the third nanosheet N3, which is the uppermost nanosheet from among the plurality of nanosheets N1, N2, and N3, and may be higher than the lower surface of the first nanosheet N1, which is the lowermost nanosheet from among the plurality of nanosheets N1, N2, and N3.

The uppermost end of the fourth source/drain layer 167 may be higher than the first vertical level LV1. The fourth source/drain layer 167 may include SiGe. In some implementations, the fourth source/drain layer 167 may include SiGe having a relatively high Ge content ratio. For example, the fourth source/drain layer 167 may include SiGe having a Ge content ratio of about 40% to about 60%.

The source/drain capping layer 169 may be formed to have a thickness of about 1 nm to about 2 nm. The uppermost end of the source/drain region 160, that is, the uppermost end of the source/drain capping layer 169, may be at the third vertical level LV3 that is higher than the first vertical level LV1. The source/drain capping layer 169 may include Si or SiGe. In some implementations, the source/drain capping layer 169 may include Si doped with an impurity such as B. When each of the second source/drain layer 163 and the source/drain capping layer 169 includes Si doped with an impurity such as B, the concentration of the impurity included in the second source/drain layer 163 may be higher than the concentration of the impurity included in the source/drain capping layer 169. In some embodiments, the source/drain capping layer 169 may have a higher Ge content ratio than each of the first source/drain layer 161 and the third source/drain layer 165 and may include SiGe having a relatively low Ge content ratio compared to the fourth source/drain layer 167. For example, the source/drain capping layer 169 may include SiGe having a Ge content ratio that is greater than about 20% and less than about 40%.

In the integrated circuit device 1, the first source/drain layer 161 and the third source/drain layer 165, which include SiGe having a relatively low Ge content ratio within the source/drain region 160, is formed to be thicker at a lower end of the source/drain region 160 than in a side portion of the source/drain region 160, to cover a side surface of each of the plurality of nanosheets N1, N2, and N3. The second source/drain layer 163 may extend between the first source/drain layer 161 and the third source/drain layer 165 and between the first source/drain layer 161 and the fourth source/drain layer 167 so that the shape of the first source/drain layer 161 remains the same without changing during a process of forming the third source/drain layer 165. Accordingly, electrical characteristics of the integrated circuit device 1 including a multi-gate MOSFET are improved and operational reliability may be ensured.

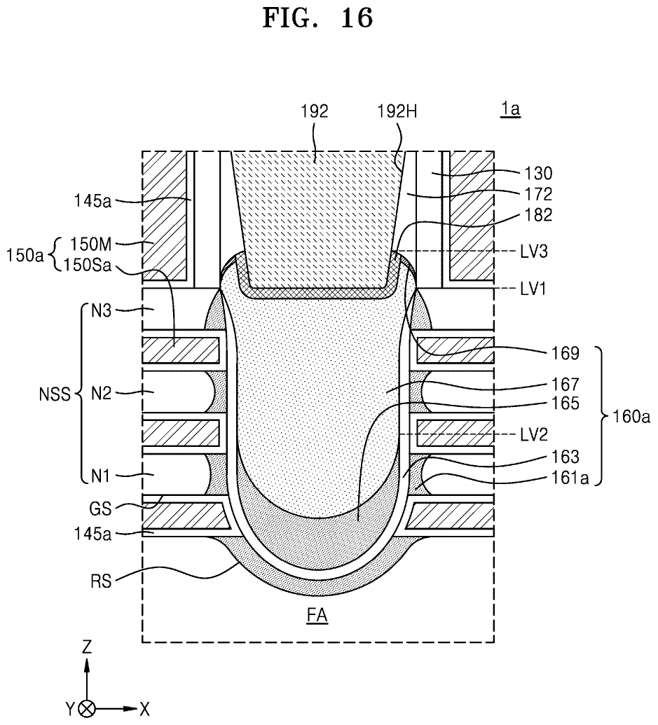

FIG. 16 is a cross-sectional view of an example of an integrated circuit device according to some implementations. Specifically, FIG. 16 is an enlarged cross-sectional view of region XV of FIG. 14B.

In FIG. 16, an integrated circuit device 1a may include a plurality of source/drain regions 160a each including a first source/drain layer 161a, the second source/drain layer 163, the third source/drain layer 165, the fourth source/drain layer 167, and the source/drain capping layer 169, a plurality of gate dielectric films 145a, and a plurality of gate electrodes 150a including the main gate portion 150M covering the upper surface of the nanosheet stacked structure NSS including the plurality of nanosheets N1, N2, and N3, and a plurality of sub-gate portions 150Sa connected to the main gate portion 150M and formed in a space between each of the plurality of nanosheets N1, N2, and N3 and the fin-type active area FA.

The first source/drain layer 161a may cover the side surface of each of the plurality of nanosheets N1, N2, and N3 and the upper surface of the fin-type active area FA positioned on the bottom surface of the recess space RS. The plurality of sub-gate portions 150Sa and the plurality of gate dielectric films 145a covering the plurality of sub-gate portions 150Sa may pass through the first source/drain layer 161a. The plurality of gate dielectric films 145a may be in contact with the second source/drain layer 163. In the process of forming the plurality of gate spaces GS described with reference to FIGS. 11 and 12, the first source/drain layer 161a may be formed by also removing the first source/drain layer 161 that fills in the plurality of sacrificial recesses 106R, and the plurality of gate dielectric films 145a and the plurality of gate electrodes 150a may be formed to fill in the plurality of gate spaces GS.

In the integrated circuit device 1a, even when the plurality of gate dielectric films 145a and the plurality of gate electrodes 150a pass through the first source/drain layer 161a, a portion of the first source/drain layer 161a in contact with the plurality of nanosheets N1, N2, and N3 may remain due to the second source/drain layer 163. Accordingly, electrical characteristics of the integrated circuit device 1a including a multi-gate MOSFET are improved and operational reliability may be ensured.

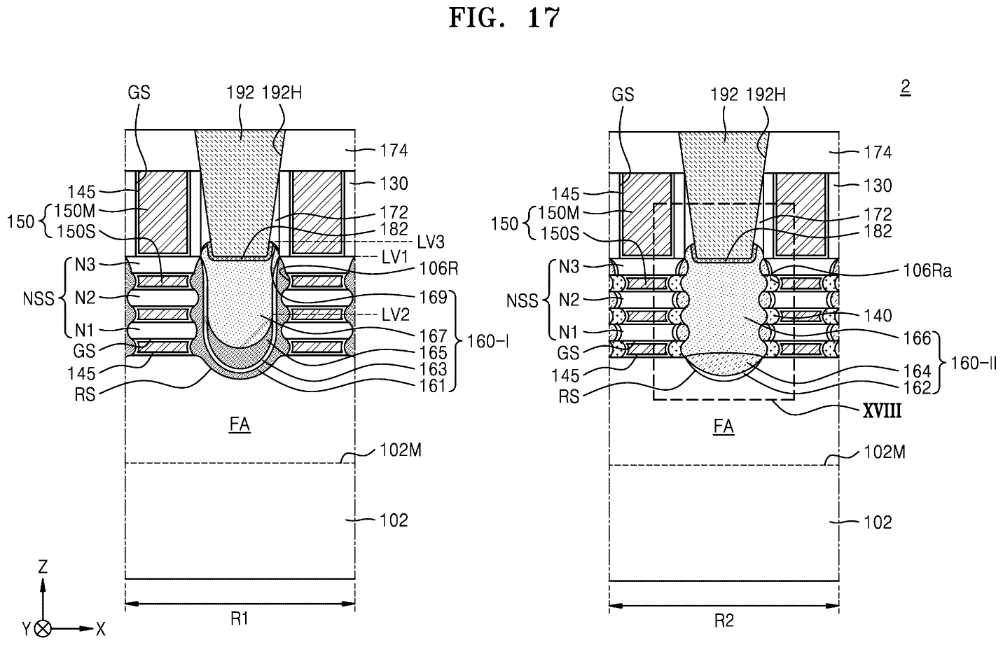

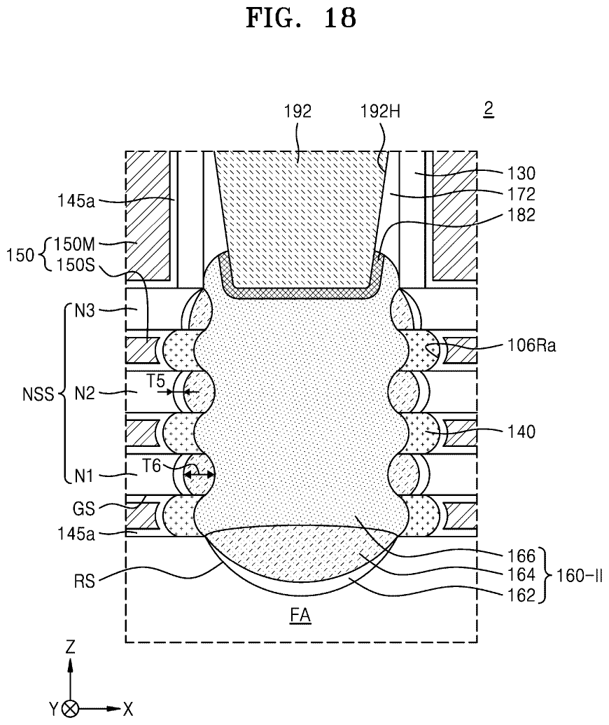

FIGS. 17 and 18 are cross-sectional views of examples of an integrated circuit device according to some implementations. Specifically, FIG. 17 is an X-Z vertical cross-sectional view, and FIG. 18 is an enlarged cross-sectional view of region XVIII of FIG. 17.

In FIGS. 17 and 18, an integrated circuit device 2 may include a first area R1 and a second area R2. A multi-gate PMOS may be provided in the first area R1, and a multi-gate NMOS may be provided in the second area R2.

In each of the first area R1 and the second area R2, the integrated circuit device 2 may include the fin-type active area FA protruding upward from the main surface 102M of the substrate 102 in the vertical direction (Z direction) and extending in the first horizontal direction (X direction), and the plurality of nanosheet stacked structures NSS facing the upper surface of the fin-type active area FA at positions spaced apart from the upper surface of the fin-type active area FA. The plurality of trenches TRE defining the plurality of fin-type active areas FA may be formed in the substrate 102. The side surfaces of the plurality of fin-type active areas FA may be covered by the device isolation film 118 filling in the plurality of trenches TRE. The plurality of nanosheet stacked structures NSS may be spaced apart from the upper surface of the fin-type active area FA. The plurality of nanosheet stacked structures NSS may include the plurality of nanosheets N1, N2, and N3 that extend in parallel with the upper surface of the fin-type active area FA on the substrate 102. The plurality of nanosheets N1, N2, and N3 forming one nanosheet stacked structure NSS may be sequentially stacked one by one on the upper surface of the fin-type active area FA.

In each of the first area R1 and the second area R2, on the fin-type active area FA, the plurality of gate electrodes 150 may extend in the second horizontal direction (Y direction) crossing the first horizontal direction (X direction). The gate electrode 150 may include the main gate portion 150M covering the upper surface of the nanosheet stacked structure NSS, and the plurality of sub-gate portions 150S connected to the main gate portion 150M and formed in a space between the fin-type active area FA and the plurality of nanosheets N1, N2, and N3, that is, on the lower side of each of the plurality of nanosheets N1, N2, and N3. The gate dielectric film 145 may be formed between the nanosheet stacked structure NSS and the gate electrode 150 and between the fin-type active area FA and the gate electrode 150.

In some implementations, from among the plurality of gate electrodes 150, at least part of the gate electrode 150 arranged in the first area R1 and formed on the nanosheet stacked structure NSS including the plurality of nanosheets N1, N2, and N3 that are in contact with a first source/drain region 160-I, and at least part of the gate electrode 150 arranged in the second area R2 and formed on the nanosheet stacked structure NSS including the plurality of nanosheets N1, N2, and N3 that are in contact with a second source/drain region 160-II may include different materials. For example, from among the plurality of gate electrodes 150, at least part of the metal-containing layer for adjusting a work function included in the gate electrode 150 arranged in the first area R1 and at least part of the metal-containing layer for adjusting a work function included in the gate electrode 150 arranged in the second area R2 may include different materials.

Between the fin-type active area FA and the nanosheet stacked structure NSS, that is, between the fin-type active area FA and the first nanosheet N1, and between the plurality of nanosheets N1, N2, and N3 adjacent to each other in the vertical direction (Z direction), that is, between the first nanosheet N1 and the second nanosheet N2 and between the second nanosheet N2 and the third nanosheet N3, a plurality of first sacrificial recesses 106R not filled with the gate dielectric film 145 and the gate electrode 150 and positioned in the first area R1 and a plurality of second sacrificial recesses 106Ra not filled with the gate dielectric film 145 and the gate electrode 150 and positioned in the second area R2 may be defined. In the first area R1, a plurality of first source/drain regions 160-I may be formed on the plurality of fin-type active areas FA, and in the second area R2, a plurality of second source/drain regions 160-II may be formed on the plurality of fin-type active areas FA. Each of the plurality of first source/drain regions 160-I and each of the plurality of second source/drain regions 160-II may be connected to one end of each of the plurality of nanosheets N1, N2, and N3 adjacent thereto.

The gate spacer 130 sequentially covering the side surface of the gate electrode 150 may be formed on the plurality of nanosheet stacked structures NSS. The gate spacer 130 may cover the side surface of the main gate portion 150M within the gate electrode 150.

The inter-gate insulating film 172 and the interlayer insulating film 174 may be sequentially formed on the plurality of first source/drain regions 160-I and the plurality of second source/drain regions 160-II.

The plurality of first contact plugs 192 may be connected to the plurality of first source/drain regions 160-I and the plurality of second source/drain regions 160-II. The plurality of first contact plugs 192 may pass through the interlayer insulating film 174 and the inter-gate insulating film 172 and be connected to the plurality of first source/drain regions 160-I and the plurality of second source/drain regions 160-II. The metal silicide film 182 may be located between the first source/drain region 160-I and the first contact plug 192 and between the second source/drain region 160-II and the first contact plug 192. The plurality of second contact plugs 194 as described above may be connected to the plurality of gate electrodes 150. The second contact plug 194 may pass through the interlayer insulating film 174 and be connected to the gate electrode 150.

Each of the plurality of first source/drain regions 160-I may include the first source/drain layer 161, the second source/drain layer 163, the third source/drain layer 165, the fourth source/drain layer 167, and the source/drain capping layer 169. The plurality of first source/drain regions 160-I may be the plurality of source/drain regions 160 shown in FIGS. 14B and 15, and the plurality of first sacrificial recesses 106R may be the plurality of sacrificial recesses 106R shown in FIGS. 14B and 15. In some implementations, similar to the source/drain regions 160a shown in FIG. 16, each of the plurality of first source/drain regions 160-I may include the first source/drain layer 161a, the second source/drain layer 163, the third source/drain layer 165, the fourth source/drain layer 167, and the source/drain capping layer 169.

The first source/drain layer 161 may be connected to the plurality of nanosheets N1, N2, and N3. In some implementations, the first source/drain layer 161 may include the plurality of protrusions 161P that fill in the plurality of first sacrificial recesses 106R. The plurality of protrusions 161P may face the plurality of sub-gate portions 150S with the gate dielectric film 145 therebetween. The first source/drain layer 161 may include SiGe having a relatively low Ge content ratio. For example, the first source/drain layer 161 may include SiGe having a Ge content ratio that is greater than 0% and about 10% or less. The second source/drain layer 163 may include a material that is different from a material of each of the first source/drain layer 161 and the third source/drain layer 165. For example, the second source/drain layer 163 may include Si. In some implementations, the second source/drain layer 163 may include Si that is not doped with impurities. In some implementations, the second source/drain layer 163 may include Si doped with an impurity such as B. In some implementations, the third source/drain layer 165 may include the same material as the first source/drain layer 161. The third source/drain layer 165 may include SiGe. The third source/drain layer 165 may include SiGe having a relatively low Ge content ratio. For example, the third source/drain layer 165 may include SiGe having a Ge content ratio that is greater than 0% and about 10% or less. In some implementations, each of the first source/drain layer 161 and the third source/drain layer 165 may include SiGe having the same Ge content ratio. The fourth source/drain layer 167 may include SiGe. In some embodiments, the fourth source/drain layer 167 may include SiGe having a relatively high Ge content ratio. For example, the fourth source/drain layer 167 may include SiGe having a Ge content ratio of about 40% to about 60%. The source/drain capping layer 169 may include Si or SiGe. In some implementations, the source/drain capping layer 169 may include Si doped with an impurity such as B. When each of the second source/drain layer 163 and the source/drain capping layer 169 includes Si doped with an impurity such as B, the concentration of the impurity included in the second source/drain layer 163 may be higher than the concentration of the impurity included in the source/drain capping layer 169. In some implementations, the source/drain capping layer 169 may have a higher Ge content ratio than each of the first source/drain layer 161 and the third source/drain layer 165 and may include SiGe having a relatively low Ge content ratio compared to the fourth source/drain layer 167. For example, the source/drain capping layer 169 may include SiGe having a Ge content ratio that is greater than about 20% and less than about 40%.

Each of the plurality of second source/drain regions 160-II may include a fifth source/drain layer 162, a sixth source/drain layer 164, and a seventh source/drain layer 166. A plurality of inner insulating spacers 140 may be located between each of the plurality of second source/drain regions 160-II and the plurality of sub-gate portions 150S. A portion of the gate dielectric film 145 may be between the plurality of sub-gate portions 150S and the plurality of inner insulating spacers 140 corresponding to each other. Each of the plurality of inner insulating spacers 140 may be in contact with the second source/drain region 160-II. The plurality of inner insulating spacers 140 may be located one by one between each of the plurality of nanosheets N1, N2, and N3. The plurality of inner insulating spacers 140 may include silicon nitride, silicon oxide, SiCN, SiBN, SiON, SiOCN, SiBCN, SiOC, or a combination thereof.

The fifth source/drain layer 162 may cover the side surface of each of the plurality of nanosheets N1, N2, and N3 and the upper surface of the fin-type active area FA positioned on the bottom surface of the recess space RS. The plurality of inner insulating spacers 140 may pass through the fifth source/drain layer 162 and be in contact with the seventh source/drain layer 166. The fifth source/drain layer 162 may be formed by using an epitaxial growth process from the fin-type active area FA exposed in the recess space RS and the plurality of nanosheets N1, N2, and N3. The fifth source/drain layer 162 may have a fifth thickness T5 on the side surface of each of the plurality of nanosheets N1, N2, and N3 and the upper surface of the fin-type active area FA. For example, the fifth thickness T5 may be about 0.5 nm to about 1.5 nm. In some implementations, the fifth thickness T5 may have substantially the same value as the third thickness T3.

The sixth source/drain layer 164 may cover the fifth source/drain layer 162. The sixth source/drain layer 164 may be formed by using an epitaxial growth process from the fifth source/drain layer 162. An upper surface of the sixth source/drain layer 164 may have a convex shape. A maximum thickness of the sixth source/drain layer 164 may be a sixth thickness T6. The sixth thickness T6 may have a greater value than the fifth thickness T5. In some implementations, the sixth thickness T6 may have a smaller value than the fourth thickness T4. The seventh source/drain layer 166 may be formed by using an epitaxial growth process from the sixth source/drain layer 164. The seventh source/drain layer 166 may be formed to fill in the recess space RS and cover the sixth source/drain layer 164. An upper surface of the seventh source/drain layer 166 may protrude from the recess space RS and may have a concave shape. An uppermost end of the seventh source/drain layer 166 may be higher than the uppermost end of the nanosheet stacked structure NSS. An uppermost end of a portion of the sixth source/drain layer 164 disposed on the upper surface of the fin-type active area FA may be at a lower level than the uppermost end of the third source/drain layer 165. An uppermost end of the second source/drain region 160-II may be higher than the uppermost end of the nanosheet stacked structure NSS. The uppermost end of the second source/drain region 160-II may be at substantially the same or similar vertical level as an uppermost end of the first source/drain region 160-I.

Each of the plurality of second source/drain regions 160-II may include Si but not Ge. Each of the fifth source/drain layer 162, the sixth source/drain layer 164, and the seventh source/drain layer 166 may include Si but not Ge. For example, the fifth source/drain layer 162 may include Si. In some implementations, the fifth source/drain layer 162 may include Si that is not doped with impurities. In some implementations, the fifth source/drain layer 162 may include Si doped with an impurity such as B. In some implementations, the fifth source/drain layer 162 and the second source/drain layer 163 may include the same material. For example, each of the sixth source/drain layer 164 and the seventh source/drain layer 166 may include one of SiAs, SiP, and SiC. In some implementations, the sixth source/drain layer 164 may include SiGa, and the seventh source/drain layer 166 may include SiP.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
a substrate;
a fin-type active area extending in a first horizontal direction on the substrate;
a nanosheet stacked structure comprising a plurality of nanosheets that are spaced apart from each other in a vertical direction and extend in parallel with an upper surface of the fin-type active area at positions spaced apart from the upper surface of the fin-type active area;
a gate electrode surrounding the nanosheet stacked structure on the fin-type active area and extending in a second horizontal direction that crosses the first horizontal direction; and
a source/drain region connected to one end of the plurality of nanosheets on the fin-type active area,
wherein the source/drain region comprises:
a first source/drain layer in contact with the upper surface of the fin-type active area and side surfaces of the plurality of nanosheets;
a second source/drain layer covering the first source/drain layer;
a third source/drain layer covering part of the second source/drain layer, the third source/drain layer having an uppermost end that is lower than an uppermost end of each of the first source/drain layer and the second source/drain layer; and
a fourth source/drain layer covering the second source/drain layer and the third source/drain layer.

2. The integrated circuit device of claim 1, wherein the third source/drain layer has a concave upper surface with respect to the upper surface of the fin-type active area.

3. The integrated circuit device of claim 2, wherein the fourth source/drain layer has a convex upper surface.

4. The integrated circuit device of claim 1,
wherein the first source/drain layer has a first thickness on the side surfaces of the plurality of nanosheets and a second thickness on the upper surface of the fin-type active area, and
wherein the second source/drain layer has a third thickness that is less than each of the first thickness and the second thickness.

5. The integrated circuit device of claim 4,
wherein the third source/drain layer has a fourth thickness in the vertical direction on the upper surface of the fin-type active area, and
wherein the fourth thickness is greater than each of the first thickness and the second thickness.

6. The integrated circuit device of claim 1,
wherein the first source/drain layer and the third source/drain layer comprise a same material, and
wherein the second source/drain layer comprises a material that is different from the material of each of the first source/drain layer and the third source/drain layer.

7. The integrated circuit device of claim 1,
wherein the first source/drain layer and the third source/drain layer comprise silicon-germanium (SiGe),
wherein the second source/drain layer comprises silicon (Si), and
the second source/drain layer excludes germanium (Ge).

8. The integrated circuit device of claim 7,
wherein each of the first source/drain layer and the third source/drain layer comprises SiGe having a first Ge content ratio, and
wherein the fourth source/drain layer comprises SiGe having a second Ge content ratio that is higher than the first Ge content ratio.

9. The integrated circuit device of claim 1,
wherein the gate electrode comprises a main gate portion extending in the second horizontal direction on the nanosheet stacked structure, and a plurality of sub-gate portions connected to the main gate portion and arranged between the fin-type active area and each of the plurality of nanosheets, and
wherein the first source/drain layer comprises a plurality of protrusions extending toward the plurality of sub-gate portions.

10. The integrated circuit device of claim 1, further comprising a gate dielectric film surrounding the gate electrode,
wherein the gate electrode comprises a main gate portion extending in the second horizontal direction on the nanosheet stacked structure, and a plurality of sub-gate portions connected to the main gate portion and arranged between the fin-type active area and each of the plurality of nanosheets, and
wherein the plurality of sub-gate portions and a portion of the gate dielectric film covering the plurality of sub-gate portions pass through the first source/drain layer so that the gate dielectric film is in contact with the second source/drain layer.

11. An integrated circuit device comprising:
a substrate having a first area and a second area;
a fin-type active area extending in a first horizontal direction in each of the first area and the second area;
a nanosheet stacked structure comprising a plurality of nanosheets in each of the first area and the second area, the plurality of nanosheets being spaced apart in a vertical direction and extending in parallel with an upper surface of the fin-type active area at positions spaced apart from the upper surface of the fin-type active area;
a gate electrode that surrounds, in each of the first area and the second area, the nanosheet stacked structure on the fin-type active area and extends in a second horizontal direction crossing the first horizontal direction; and
a first source/drain region that is connected, in the first area, to one end of the plurality of nanosheets on the fin-type active area,
wherein the first source/drain region comprises
a first source/drain layer in contact with the upper surface of the fin-type active area and side surfaces of the plurality of nanosheets, the first source/drain layer having a first thickness on the side surfaces of the plurality of nanosheets and a second thickness on the upper surface of the fin-type active area,
a second source/drain layer covering the first source/drain layer and having a third thickness that is less than each of the first thickness and the second thickness,
a third source/drain layer covering part of the second source/drain layer, the third source/drain layer having an uppermost end that is lower than an uppermost end of each of the first source/drain layer and the second source/drain layer, and
a fourth source/drain layer covering the second source/drain layer and the third source/drain layer, and
wherein the second source/drain layer extends between the first source/drain layer and the third source/drain layer and between the first source/drain layer and the fourth source/drain layer.

12. The integrated circuit device of claim 11,
wherein the uppermost end of the third source/drain layer is lower than an uppermost end of the nanosheet stacked structure, and
wherein the uppermost end of the third source/drain layer is higher than a lowermost end of the nanosheet stacked structure.

13. The integrated circuit device of claim 12,
wherein the third source/drain layer has a fourth thickness in the vertical direction on the upper surface of the fin-type active area, and
wherein the fourth thickness is greater than the first thickness.

14. The integrated circuit device of claim 11,
wherein the third source/drain layer has a concave upper surface with respect to the upper surface of the fin-type active area, and
wherein the fourth source/drain layer has a convex upper surface with respect to the upper surface of the fin-type active area.

15. The integrated circuit device of claim 11,
wherein each of the first source/drain layer and the third source/drain layer comprises silicon-germanium (SiGe) having a first germanium (Ge) content ratio,
wherein the second source/drain layer comprises silicon (Si),
wherein the second source/drain layer excludes Ge, and
wherein the fourth source/drain layer comprises SiGe having a second Ge content ratio that is higher than the first Ge content ratio.

16. The integrated circuit device of claim 11, further comprising a second source/drain region connected, in the second area, to one end of the plurality of nanosheets on the fin-type active area,
wherein the second source/drain region comprises a fifth source/drain layer in contact with the upper surface of the fin-type active area and the side surfaces of the plurality of nanosheets, a sixth source/drain layer covering the fifth source/drain layer and having a convex upper surface, and a seventh source/drain layer covering the sixth source/drain layer and having a convex upper surface,
wherein an uppermost end of a portion of the sixth source/drain layer disposed on the upper surface of the fin-type active area is at a lower vertical level than the uppermost end of the third source/drain layer, and
wherein each of an uppermost end of the fourth source/drain layer and an uppermost end of the seventh source/drain layer is at a higher vertical level than an uppermost end of the nanosheet stacked structure.

17. The integrated circuit device of claim 16,
wherein the second source/drain region comprises silicon (Si), and
wherein the second source/drain region excludes germanium (Ge).

18. The integrated circuit device of claim 16,
wherein the gate electrode comprises a main gate portion extending in the second horizontal direction on the nanosheet stacked structure, and a plurality of sub-gate portions connected to the main gate portion and arranged between the fin-type active area and each of the plurality of nanosheets, and
wherein a plurality of inner insulating spacers are between the second source/drain region and the plurality of sub-gate portions.

19. An integrated circuit device comprising:
a substrate having a first area and a second area;
a fin-type active area extending in a first horizontal direction in each of the first area and the second area;
a nanosheet stacked structure comprising a plurality of nanosheets in each of the first area and the second area, the plurality of nanosheets being spaced apart in a vertical direction and extending in parallel with an upper surface of the fin-type active area at positions spaced apart from the upper surface of the fin-type active area;
a gate electrode, that surrounds, in each of the first area and the second area, the nanosheet stacked structure on the fin-type active area and extends in a second horizontal direction crossing the first horizontal direction;
a first source/drain region, that is connected, in the first area, to one end of the plurality of nanosheets on the fin-type active area; and
a second source/drain region, that is connected, in the second area, to one end of the plurality of nanosheets on the fin-type active area,
wherein the first source/drain region comprises
a first source/drain layer in contact with the upper surface of the fin-type active area and side surfaces of the plurality of nanosheets, the first source/drain layer having a first thickness on the side surfaces of the plurality of nanosheets and a second thickness on the upper surface of the fin-type active area,
a second source/drain layer covering the first source/drain layer and having a third thickness that is less than each of the first thickness and the second thickness,
a third source/drain layer covering part of the second source/drain layer, the third source/drain layer having an uppermost end that is lower than an uppermost end of each of the first source/drain layer and the second source/drain layer and a concave upper surface, and
a fourth source/drain layer covering the second source/drain layer and the third source/drain layer,
wherein the second source/drain region comprises
a fifth source/drain layer in contact with the upper surface of the fin-type active area and the side surfaces of the plurality of nanosheets,
a sixth source/drain layer covering the fifth source/drain layer and having a convex upper surface, and
a seventh source/drain layer covering the sixth source/drain layer, the seventh source/drain layer having a convex upper surface, and
wherein each of an uppermost end of the fourth source/drain layer and an uppermost end of the seventh source/drain layer is at a higher vertical level than an uppermost end of the nanosheet stacked structure.

20. The integrated circuit device of claim 19, further comprising a gate dielectric film surrounding the gate electrode,
wherein the gate electrode comprises a main gate portion extending in the second horizontal direction on the nanosheet stacked structure, and comprises a plurality of sub-gate portions connected to the main gate portion and arranged between the fin-type active area and each of the plurality of nanosheets,
wherein, in the first area, the plurality of sub-gate portions and a portion of the gate dielectric film covering the plurality of sub-gate portions extend into the first source/drain layer so that the gate dielectric film is in contact with the second source/drain layer, and
wherein, in the second area, a plurality of inner insulating spacers are between the second source/drain region and the plurality of sub-gate portions.
